(19) United States
(12) Patent Application Publication
(10) Pub. No.: US 2008/0070343 A1
(43) Pub. Date: Mar. 20, 2008

(54) Methods for forming an organic thin film using solvent effects, organic thin film formed by the method, and organic electronic device comprising organic thin film

(75) Inventors: Jung Seok Hahn, Yongin-si (KR); Bang-Lin Lee, Yongin-si (KR); Tae-Sang Kim, Yongin-si (KR); Sang-Yoon Lee, Yongin-si (KR); Hyun Sik Moon, Yongin-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD

(21) Appl. No.: 11/730,317

(22) Filed: Mar. 30, 2007

(30) Foreign Application Priority Data
Sep. 18, 2006 (KR) 10-2006-0090109

(51) Int. Cl. H01L 51/00

(52) U.S. Cl. 438/99; 252/510

(57) ABSTRACT

Disclosed is a method for forming an organic thin film using a good solvent and a non-solvent to promote crystallization of an organic material. The method may enable the formation of a dense, uniform, highly ordered organic thin film by a wet process in a simple and an economical manner. Therefore, the organic thin film may be used as a gate insulating layer or a semiconductor layer to fabricate an organic electronic device having improved electrical properties, e.g., increased charge carrier mobility. Further disclosed are an organic thin film formed by the method and an organic electronic device including the organic thin film.

### PRIORITY STATEMENT

This non-provisional application claims priority under 35 U.S.C. § 119 to Korean Patent Application No. 2006-0090109, filed on Sep. 18, 2006, in the Korean Intellectual Property Office (KIPO), the entire contents of which are herein incorporated by reference.

### BACKGROUND

1. Field

Example embodiments relate to a method for forming an organic thin film using solvent effects and its applications. Other example embodiments relate to a method for forming an organic thin film in which a good solvent and a non-solvent may be used to promote crystallization of an organic material, an organic thin film formed by the method, and an organic electronic device including the organic thin film.

2. Description of the Related Art

Generally, the characteristics of organic electronic devices may be determined by various factors, e.g., density, uniformity, cleanness, adhesiveness and ordering degree, of organic thin films for use in the organic electronic devices. These factors of organic thin films may be affected by processes for forming the thin films, e.g. film formation processes.

The formation of dense and uniform thin films by vacuum evaporation may be dependent on the degree of crystallization of materials for the thin films. Vacuum evaporation has the problem of a complicated and troublesome procedure and may be thus inefficient in terms of processing. Because vacuum evaporation requires an increased temperature of about 200° C. to about 400° C. to form thin films, various substrates may be limited in their use and printing processes may be difficult to apply to the fabrication of devices using the thin films. In recent years, room-temperature wet processes have been employed to form thin films in an economical and simple manner. For example, room-temperature wet processes utilizing the crystallization of organic polymeric materials have attracted attention.

When performing wet processes using organic polymeric materials, the performance (e.g., charge carrier mobility) of organic thin films may be determined by the degree of crystallization or interfacial properties of the polymeric materials through n-n stacking of the polymeric materials within amorphous films. The performance of organic thin films formed by room-temperature wet processes may not reach that of organic thin films formed by vacuum evaporation. This may be because rapid volatilization or evaporation of solvents used during wet processes partially permits the crystallization of polymeric materials.

In recent years, a great deal of research has been conducted in various fields to provide organic thin films with better performance by wet processes. Most of the research aims at the improvement of the characteristics of thin films by pretreatment of a soluble organic material in a solution or treatment of the solution during processing. For example, some approaches, e.g., annealing during processing, introduction of multilayer protective layer structures, addition of other additives and surface treatment of thin films, may be effective in improving the characteristics of thin films and devices. These approaches have a limitation in improving the characteristics of thin films in that complicated additional steps may be required and the treatments may be done in a state where the degree of freedom of materials for thin films is limited.

The related art discloses a process for the production of an organic semiconductor film using an organic semiconductor material and a mixture of at least two solvents having different polarities or vapor pressures. This process may prevent or reduce rapid evaporation of the solvents during film formation to improve the ordering degree of the thin film, thus achieving improved electrical properties.

There remains a need in the art to develop a novel technique for providing an organic thin film and a device with improved performance by a simple and economical room-temperature wet process.

### SUMMARY

Example embodiments have been made to meet the technical need in the art, and example embodiments provide a novel method for forming an organic thin film using solvent effects in an easy manner by a simple wet process in which a good solvent and a non-solvent may be used to induce aggregation of an organic material in a solution and subsequently to promote crystallization of the organic material by virtue of the aggregation, thereby achieving improved physical properties and improved surface characteristics of the organic thin film. Example embodiments provide an inexpensive organic electronic device with improved electrical properties which may include a thin film formed by the method.

In accordance with example embodiments, a method for forming an organic thin film may include adding a non-solvent to a composition including an organic material and a good solvent, and applying the mixture to a substrate to form a thin film.

In accordance with example embodiments, a method for forming an organic thin film may include applying a composition including an organic material and a good solvent to a substrate, and applying a non-solvent thereto to form a thin film.

In accordance with example embodiments, a method for forming an organic thin film may include applying a non-solvent to a substrate, and applying a composition including an organic material and a good solvent thereto to form a thin film.

In accordance with example embodiments, there is provided an organic thin film formed by one of the methods. In accordance with example embodiments, there is also provided an organic electronic device including the organic thin film as a gate insulating layer and a semiconductor layer.

### BRIEF DESCRIPTION OF THE DRAWINGS

Example embodiments will be more clearly understood from the following detailed description taken in conjunction with the accompanying drawings. FIGS. 1-2 represent non-limiting, example embodiments as described herein.

FIG. 1 is a diagram schematically illustrating the aggregation of an organic material induced by the addition of a non-solvent according to example embodiments; and

FIG. 2 is a graph showing the current transfer characteristics of organic thin film transistors fabricated in Example 1 and Comparative Example 1 of example embodiments.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Example embodiments will now be described in greater detail with reference to the accompanying drawings. In the drawings, the thicknesses and widths of layers are exaggerated for clarity. Example embodiments may, however, be embodied in many different forms and should not be construed as limited to the example embodiments set forth herein. Rather, these example embodiments are provided so that this disclosure will be thorough and complete, and will fully convey the scope of example embodiments to those skilled in the art.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Example embodiments provide a method for forming a dense, uniform, highly ordered organic thin film in a relatively easy manner in which a good solvent and a non-solvent may be used to induce aggregation of an organic material in a solution and subsequently to promote crystallization of the organic material by virtue of the aggregation. According to the method of example embodiments, although the solvents are rapidly volatilized, the crystallization of the organic material may be promoted by virtue of the previous aggregation of the organic material, thus enabling formation of an organic thin film with improved physical properties and improved surface characteristics in a simple and economical manner.

Example embodiments provide methods for forming an organic thin film. A method may include adding a non-solvent to a composition including an organic material and a good solvent, and applying the mixture to a substrate. A method may also include applying a composition including an organic material and a good solvent to a substrate, and applying a non-solvent thereto. Another method may include applying a non-solvent to a substrate, and applying a composition including an organic material and a good solvent thereto.

The methods according to example embodiments may be suitably chosen by those skilled in the art according to the intended applications. When little aggregation or precipitation occurs after addition of a non-solvent, one method may be applied to the formation of an organic thin film. When severe aggregation (or precipitation) occurs after addition of a non-solvent, the other methods may be applied to the formation of an organic thin film. A more detailed explanation of the respective methods according to example embodiments will be provided below.

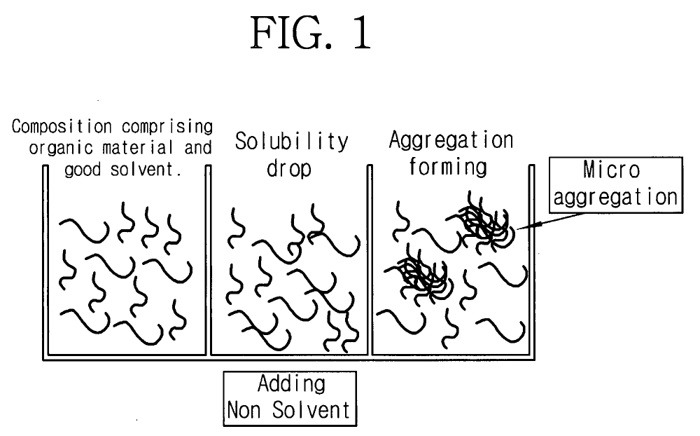

A non-solvent may be added to a composition including an organic material and a good solvent. The addition of the non-solvent may dramatically lower the solubility of the solvents for the organic material to induce formation of fine aggregates or precipitates of the organic material, and as a result, the crystallization of the organic material may be promoted in the subsequent step. FIG. 1 schematically illustrates the formation of aggregates of the organic material induced by the addition of the non-solvent.

All organic materials that are available in the field of organic electronic devices may be used in the method of example embodiments. The type of organic material may be properly selected by those skilled in the art according to the intended applications and needs. For example, the organic material may be an organic semiconductor material and/or an organic insulating material.

Any organic semiconductor material and/or organic insulating material that have hitherto been known may be used without limitation, and specific examples thereof may include low-molecular weight materials, oligomeric materials and/or polymeric materials. A polymeric material may be used as the organic material in the method of example embodiments because the method of example embodiments may be advantageous over conventional methods for forming thin films in terms of solubility.

Specific examples of the organic semiconductor material may include anthracene, tetracene, pentacene, melocyanine, copper phthalocyanine, perylene, rubrene, coronen, anthradithiophene, polyfluorene, polyacetylene, polydiacetylene. polypyrrole, polythiophene, oligothiophene, polyselenophene, polyisothianaphthene, polyarylenevinylene, polyaniline, polyazulene, polypyrene, polycarbazole, polyfuran, polyphenylene, polyindole, polypyridazine, polyacene, polythienylthiazole and/or derivatives thereof. These organic semiconductor materials may be used alone and/or as a mixture thereof.

Specific examples of the organic insulating material may include, but may not be limited to, polyimide, benzocyclobutene (BCB), parylene, polyacrylate, polyvinyl alcohol, polyvinylphenol, and derivatives thereof. These organic insulating materials may be used alone and/or as a mixture thereof.

The term “good solvent” as used herein refers to a solvent that itself has an increased solubility and may dissolve the organic material as a solute. The term “non-solvent” as used herein refers to a solvent that itself has a relatively low solubility and may not dissolve the organic material as a solute to cause precipitation or aggregation of the organic material.

Specific kinds of the “good solvent” and the “non-solvent” may vary depending on various parameters, e.g., type, molecular weight and treatment conditions, of the organic material used, and may be suitably determined by those skilled in the art according to the intended applications taking into consideration the above conditions.

Where the organic material is poly(3-hexylthiophene-2,5-diyl) (P3HT, molecular weight: about 33,000) as a semiconductor material, the good solvent may be at least one solvent selected from chlorobenzene, chloroform, tetrahydronaphthalene, tetrachlorobenzene, tetrahydrofuran, toluene, xylene, indole and/or other solvents, and the non-solvent may be at least one solvent selected from water, alcohols, e.g., methyl alcohol, ethyl alcohol and n-butyl alcohol, acetone, acetonitrile and/or other solvents.

Where the organic material is an insulating material, the good solvent may be at least one solvent selected from chloroform, chlorobenzene and/or other solvents, and the non-solvent may be at least one solvent selected from alcohols, acetonitrile and/or other solvents.

The good solvent may be a solvent having a solubility of about 0.05% to about 20% by weight for the organic material and the non-solvent may be a solvent having a solubility of about 0.001% to about 0.05% by weight for the organic material. The good solvent may be a solvent having a solubility of about 1% to about 10% by weight for the organic material and the non-solvent may be a solvent having a solubility of about 0.01% to about 0.03% by weight for the organic material. The solubility of these solvents for the organic material may not be limited to these ranges. Depending on the type of organic material used, the solubility of the good solvent and the non-solvent may be outside the ranges defined above.

The composition may include about 0.1% to about 50% by weight of the organic material and about 50% to about 99.9% by weight of the good solvent, but may not be limited to these contents. The composition may further include about 0.01% to about 10% by weight of at least one additive selected from dispersants, defoaming agents, fillers and/or viscosity modifiers. The types and amounts of the additives may be suitably selected by those skilled in the art according to the intended applications and needs. For better dispersibility, if desired, the composition may be subjected to sonication or agitation according to the judgment of those skilled in the art.

The amount of non-solvent added may be appropriately determined by those skilled in the art taking into consideration various parameters, e.g., kind and molecular weight, of the organic material such that aggregation or precipitation of the organic material occurs. The volume ratio of the good solvent to the non-solvent added may be from about 1:1 to about 1,000:1, for example, from about 1:1 to about 20:1. The addition of the non-solvent in an amount exceeding the range may make it difficult to form an organic thin film due to a repulsive interaction with the solute.

The mixture, which is composed of the composition and the non-solvent, may be applied to a substrate to form a thin film. For example, the mixture, in which fine aggregates of the organic material are formed by the addition of the non-solvent, may be applied to a substrate by a common coating or printing process in accordance with general wet processing procedure, followed by drying to form a thin film.

The substrate may not be especially limited so long as example embodiments are not impaired. For example, the substrate may be a transparent substrate, or may be made of a semiconductor material or an insulating material. For example, the transparent substrate may be coated with a semiconductor material depending on the structure of a device, to which a thin film according to example embodiments may be applied. Specific examples of such transparent substrates may include glass substrates, silicon wafers, indium tin oxide (ITO) glass substrates, quartz substrates, silica-coated substrates, alumina-coated substrates and/or plastic substrates. These transparent substrates may be suitably selected by those skilled in the art according to the intended applications.

As mentioned above, the application of the mixture may be carried out by a common coating or printing process. For example, the application may be carried out by printing, ink-jetting, drop casting, dip coating, spin casting, stamping, screen printing and/or solution-casting, in view of an increased area application and ease and convenience of the application, e.g., printing, drop casting and spin casting processes.

The application processes of the mixture may be appropriately selected and determined by those skilled in the art according to the desired needs. The application may be carried out at about 20° C. to about 100° C., for example, about 40° C. to about 60° C., for about 1 minute to about 12 hours, for example, about 10 minutes to about 5 hours.

If desired, the surface of the substrate may be pretreated before application of the mixture to improve the adhesiveness of the substrate and reduce the change in the difference of interaction between the substrate material and the solvents. Any method that is known in the field of organic electronic devices may be employed to pretreat the surface of the substrate, and specific examples thereof may include methods associated with the use of a self-assembled monolayer formed of octyltrichlorosilane (OTS), the use of a buffer layer, e.g., a polymethylmethacrylate (PMMA) thin film, and the use of O₂ plasma for varying surface physical properties, but may not be limited to these methods.

The method of example embodiments may further include annealing the final thin film at about 50° C. to about 200° C. for about one minute to about one hour to further improve the density and uniformity of the thin film.

In another method, a composition including an organic material and a good solvent may be applied to a substrate so as to come into initial contact with the substrate. The composition may be used in an amount sufficient so that the good solvent may not be readily evaporated. The amount of the composition used may not be particularly restricted, and may be appropriately selected by those skilled in the art. For example, the composition may be used in such an amount as to form a channel.

The substrate, the organic material, the good solvent, the composition, the application process and the treatment conditions used herein are the same as those described above, and hence detailed explanations thereof are omitted. As in the other method, the surface of the substrate may be pretreated before application of the composition.

A non-solvent may be applied to the composition, which is previously applied to the substrate, so as to come into secondary contact with the composition to form a thin film. For example, the non-solvent may be applied to the composition in a state where the good solvent contained in the composition remains on the substrate so as to come into contact with the composition in a solution state for a short time.

This short contact may lower the solubility of the solvents for the organic material to induce formation of fine aggregates of the organic material, and as a result, the crystallization of the organic material may be promoted during drying to form the final thin film.

The non-solvent, the application process and the treatment conditions used herein are the same as those described above, and hence detailed explanations thereof are omitted. The method of example embodiments may further include annealing the final thin film.

In another method, a non-solvent may be applied to a substrate so as to come into initial contact with the substrate. The non-solvent may be used in an amount sufficient so that it is not readily evaporated. The amount of non-solvent used may not be particularly restricted, and may be appropriately selected by those skilled in the art. For example, the non-solvent may be used in such an amount as to form a channel.

The substrate, the non-solvent, the application process and the treatment conditions used herein are the same as those described above, and hence detailed explanations thereof are omitted. As in one of the other methods, the surface of the substrate may be pretreated before application of the non-solvent to the substrate.

A composition including an organic material and a good solvent may be applied to the non-solvent, which is previously applied to the substrate, so as to come into secondary contact with the non-solvent to form a thin film. For example, the composition may be applied to the non-solvent in a state where the non-solvent remains on the substrate so as to come into contact with the non-solvent for a short time. This short contact may lower the solubility of the solvents for the organic material to induce formation of fine aggregates of the organic material, and as a result, the crystallization of the organic material may be promoted during drying to form the final thin film.

The organic material, the good solvent, the composition, the application process and the treatment conditions used herein are the same as those described above, and hence detailed explanations thereof are omitted. The method of example embodiments may further include annealing the final thin film.

According to some of the methods, because the short contact between the good solvent and the non-solvent may achieve the desired purposes, no special problem may be caused despite severe aggregation or precipitation induced by the addition of the non-solvent.

According to the methods of example embodiments, when the organic material is in a freer state in terms of degree of freedom, e.g. when the organic material is dissolved in the good solvent, in a common wet process, environmental changes (e.g. addition of the non-solvent or contact with the non-solvent) may be made to induce formation of aggregates or precipitates of the organic material and subsequently to permit the aggregates or precipitates to act as catalysts for the formation of the final thin film. Therefore, regardless of the volatilization rate of the solvents, the organic thin film may be dense, uniform and highly ordered, may have improved physical properties and improved surface characteristics, and may be formed in a relatively easy manner.

For example, where the organic material is a polymeric semiconductor material, the addition of the non-solvent or contact with the non-solvent may lower the solubility of the polymeric semiconductor material in the good solvent to form fine aggregates of the polymeric semiconductor material, and as a result, the molecules of the polymeric semiconductor material may be in close proximity to each other to readily form n-n stacking of the polymeric semiconductor material, which is believed to increase the degree of crystallization or charge carrier mobility of the polymeric semiconductor material. Where the organic material is a polymeric insulator material, the addition of the non-solvent or contact with the non-solvent may cause the occurrence of a partial self-seeding process, and as a result, the degree of crystallization of the polymeric insulator material may be increased, which may lead to an improvement in the physical properties of the final thin film and an increase in the relative dielectric constant value of the final thin film.

Therefore, the organic thin film formed by one of the methods according to example embodiments may be useful as a gate insulating layer or a semiconductor layer of an organic electronic device. An organic electronic device using the organic thin film of example embodiments may be produced at a reduced cost and may exhibit improved electrical properties, e.g., increased charge carrier mobility, and therefore, the organic electronic device may be effectively used to fabricate a variety of display devices, including liquid crystal displays (LCDs), plasma displays, field emission displays (FEDs), light-emitting diodes (LEDs) and/or organic light-emitting devices (OLEDs).

Example embodiments provide an organic electronic device including an organic thin film formed by one of the methods according to example embodiments as a gate insulating layer or a semiconductor layer. The thickness of the organic thin film may be in the range of about 100 Å to about 1,000 Å, but may not be limited to this range. The organic thin film may be patterned by a common technique before use according to the intended applications and needs. Examples of the organic electronic device may include, but may not be limited to, thin film transistors, solar cells and/or polymer memory devices.

Where the organic electronic device of example embodiments is a thin film transistor, a substrate, a gate electrode and source-drain electrodes of the thin film transistor may be formed using materials that are commonly known in the art.

For example, a material for the substrate may be suitably selected from silica, glass and/or plastic, by those skilled in the art according to the intended applications. Materials for the gate electrode, the source electrode and the drain electrode may be selected from: metals, including gold (Au), silver (Ag), aluminum (Al), nickel (Ni), molybdenum (Mo), tungsten (W) and/or chromium (Cr); alloys thereof, e.g., a molybdenum/tungsten (Mo/W) alloy; metal oxides, including indium-tin oxide (ITO) and/or indium-zinc oxide (IZO); and electrically conductive polymers, including polythiophene, polyaniline, polyacetylene, polypyrrole, polyphenylene vinylene, and/or polyethylenedioxythiophene (PEDOT)/polystyrenesulfonate (PSS) mixtures.

The organic electronic device of example embodiments may have any structure, for example, a bottom contact, top contact and/or top gate structure. The structure of the organic electronic device according to example embodiments may be modified so long as example embodiments are not impaired.

Hereinafter, example embodiments will be explained in more detail with reference to the following examples. However, these examples are given for the purpose of illustration only and are not intended to limit example embodiments.

### EXAMPLES

### [Fabrication of Organic Thin Film Transistors]

### Example 1

About 1 wt % of poly(3-hexylthiophene) (P3HT) (molecular weight: about 33,000) was dissolved in chlorobenzene at about 45° C., and then about 10 parts by volume of acetonitrile was added to the solution. The mixture was dispersed by sonication for about 3 hours to prepare an organic semiconductor composition. A molybdenum/tungsten (Mo/W) alloy was deposited to a thickness of about 1,000 Å on a clean glass substrate by sputtering to form a gate electrode. Then a mixture of the methacryloxypropyltrimethoxysilane polymer and tetrabutoxy titanate (Ti(OC₄H₉)₄)(about 70:30 weight ratio) was dissolved in butanol a concentration of about 10 wt %. The solution was spin-coated to a thickness of about 7,000 Å thereon to form a gate insulating layer. The organic semiconductor composition was spin-cast at about 1,000 rpm to a thickness of about 800 Å on the gate insulating layer, and baked under a nitrogen atmosphere at about 100° C. for about 10 minutes to form a semiconductor layer. Thereafter, gold (Au) was deposited to a thickness of about 700 Å on the semiconductor layer by metal vapor deposition to form source-drain electrodes, completing fabrication of an organic thin film transistor with a top contact structure.

### Example 2

About 1 wt % of poly(3-hexylthiophene) (P3HT) (molecular weight: about 33,000) was dissolved in chlorobenzene at about 45° C., and then about 10 parts by volume of butyl alcohol was added to the solution. The mixture was dispersed by sonication for about 3 hours to prepare an organic semiconductor composition. A molybdenum/tungsten (Mo/W) alloy was deposited to a thickness of about 1,000 Å on a clean glass substrate by sputtering to form a gate electrode, and then an organic insulator material was spin-coated to a thickness of about 7,000 Å thereon to form a gate insulating layer. As the organic insulator material, the same material as that used in Example 1 was used. The organic semiconductor composition was spin-cast at about 1,000 rpm to a thickness of about 800 Å on the gate insulating layer, and baked under a nitrogen atmosphere at about 100° C. for about 10 minutes to form a semiconductor layer. Thereafter, gold (Au) was deposited to a thickness of about 700 Å on the semiconductor layer by metal vapor deposition to form source-drain electrodes, completing fabrication of an organic thin film transistor with a top contact structure.

### Example 3

About 1 wt % of poly(3-hexylthiophene) (P3HT) (molecular weight: about 33,000) was dissolved in chlorobenzene at about 45° C. and dispersed by sonication for about 3 hours to prepare an organic semiconductor composition. A molybdenum/tungsten (Mo/W) alloy was deposited to a thickness of about 1,000 Å on a clean glass substrate by sputtering to form a gate electrode, and then an organic insulator material was spin-coated to a thickness of about 7,000 Å thereon to form a gate insulating layer. As the organic insulator material, the same material as that used in Example 1 was used. A predetermined or given amount of the organic semiconductor composition was drop-cast on the gate insulating layer. Before evaporation of the solvent, butyl alcohol was dropped on the organic semiconductor composition. The butyl alcohol was used in an amount of about 10% by volume, based on the volume of the composition. The resulting structure was baked under a nitrogen atmosphere at about 100° C. for about 30 minutes to form a semiconductor layer. Thereafter, gold (Au) was deposited to a thickness of about 700 Å on the semiconductor layer by metal vapor deposition to form source-drain electrodes, completing fabrication of an organic thin film transistor with a top contact structure.

### Example 4

About 1 wt % of P3HT (molecular weight: about 33,000) was dissolved in chlorobenzene at about 45° C. and dispersed by sonication for about 3 hours to prepare an organic semiconductor composition. A molybdenum/tungsten (Mo/W) alloy was deposited to a thickness of about 1,000 Å on a clean glass substrate by sputtering to form a gate electrode, and then an organic insulator material was spin-coated to a thickness of about 7,000 Å thereon to form a gate insulating layer. As the organic insulator material, the same material as that used in Example 1 was used. A slight amount of butyl alcohol was drop-cast on the gate insulating layer. Before evaporation of the butyl alcohol, the organic semiconductor composition was dropped on the butyl alcohol. The organic semiconductor composition was used in an amount of about 90% by volume, based on the volume of the alcohol applied. The resulting structure was baked under a nitrogen atmosphere at about 100° C. for about 30 minutes to form a semiconductor layer. Thereafter, gold (Au) was deposited to a thickness of about 700 Å on the semiconductor layer by metal vapor deposition to form source-drain electrodes, completing fabrication of an organic thin film transistor with a top contact structure.

### Example 5

About 1 wt % of P3HT (molecular weight: about 33,000) was dissolved in chlorobenzene at about 45° C., and then about 10 parts by volume of butyl alcohol was added to the solution. The mixture was dispersed by sonication for about 3 hours to prepare an organic semiconductor composition. Separately, about 15 wt % of polymethylmethacrylate (PMMA, molecular weight: about 112,000) was stirred in toluene for about 24 hours in a place protected from light to obtain a solution, and butyl alcohol was added in an amount of about 10% by volume to the solution to prepare an organic insulator composition. A molybdenum/tungsten (Mo/W) alloy was deposited to a thickness of about 1,000 Å on a clean glass substrate by sputtering to form a gate electrode, and then the insulator composition was spin-coated thereon, followed by calcination at about 200° C. to form a gate insulating layer. A predetermined or given amount of the organic semiconductor composition was spin-cast on the gate insulating layer and baked under a nitrogen atmosphere at about 100° C. for about 30 minutes to form a semiconductor layer. Thereafter, gold (Au) was deposited to a thickness of about 700 Å on the semiconductor layer by metal vapor deposition to form source-drain electrodes, completing fabrication of an organic thin film transistor with a top contact structure.

### Comparative Example 1

An organic thin film transistor was fabricated in the same manner as in Example 1, except that no acetonitrile was added to prepare the organic semiconductor composition.

### Comparative Example 2

An organic thin film transistor was fabricated in the same manner as in Example 2, except that no butyl alcohol was added to prepare the organic semiconductor composition.

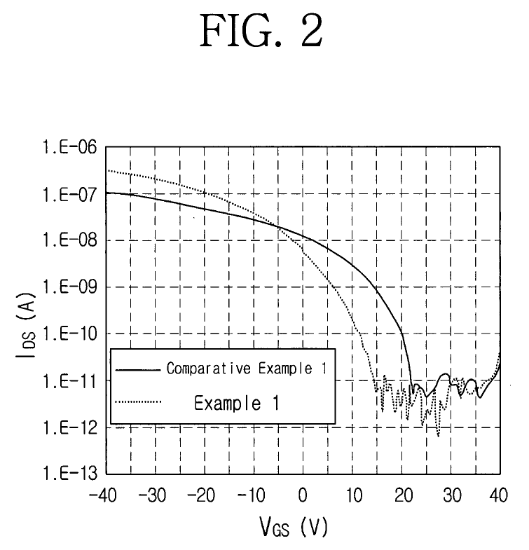

To evaluate the electrical properties of the organic thin film transistors fabricated in Example 1 and Comparative Example 1, the current transfer characteristics of the devices were measured using a semiconductor analyzer (KEITHLEY, 4200-SCS), and the obtained results are shown in FIG. 2.

From the graph of FIG. 2, the addition of the non-solvent increased the on-current of the device according to example embodiments without any change in off-current.

The charge carrier mobility and on/off current ratio of the organic thin film transistors fabricated in Examples 1 and 2 and Comparative Examples 1 and 2 were measured in accordance with the following respective procedures. The results are shown in Table 1.

1) Charge Carrier Mobility

The charge carrier mobility was calculated from the slope of a graph representing the relationship between (I_{SD})^{1/2} and V_{G}, which was plotted from the following current equations in the saturation region:

$${I}_{SD} = \frac{{WC}_{0}}{2 L} {μ ( {V}_{G} - {V}_{T} )}^{2}$$

$$\sqrt{{I}_{SD}} = \sqrt{\frac{μ {C}_{0} W}{2 L}} ( {V}_{G} - {V}_{T} )$$

$$slope = \sqrt{\frac{μ {C}_{0} W}{2 L}}$$

$${μ}_{FET} = {( slope )}^{2} \frac{2 L}{{C}_{0} W}$$

In the above equations, I_{SD}: source-drain current, p and μ_{FET}: charge carrier mobility, C_{O}: capacitance of oxide film, W: channel width, L: channel length, V_{G}: gate voltage, and V_{T}: threshold voltage.

2) On/off current ratio (Iₒₙ/I_{off})

The Iₒₙ/I_{off} ratio was determined from a ratio of a maximum or increased current in the on-state to a minimum or reduced current in the off-state. The Iₒₙ/I_{off} ratio is represented by the following equation:

$$\frac{{I}_{on}}{{I}_{off}} = ( \frac{μ}{σ} ) \frac{{C}_{o}^{2}}{{qN}_{A} {t}^{2}} {V}_{D}^{2}$$

wherein Iₒₙ: maximum or increased current, I_{off}: off-state leakage current, μ: charge carrier mobility, σ: conductivity of thin film, q: electric charge, NA: electric charge density, t: thickness of semiconductor film, Co: capacitance of oxide film, and V_{D}: drain voltage. The off-state leakage current (I_{off}), which is a current flowing in the off-state, was determined from the minimum or reduced current in the off-state.

TABLE 1

| | Charge carrier | | | |
|---|---|---|---|---|
| Example No. | mobility | I_{On}/I_{Off} | I_{On} | I_{Off} |
| Comparative | 0.00723 | 4.13 × 10⁴ | 1.09 × 10⁻⁷ | 2.64 × 10⁻¹² |
| Example 1 | | | | |
| Comparative | 0.01099 | 1.60 × 10⁵ | 1.21 × 10⁻⁷ | 7.55 × 10⁻¹³ |
| Example 2 | | | | |
| Example 1 | 0.02614 | 1.82 × 10⁵ | 3.20 × 10⁻⁷ | 1.76 × 10⁻¹² |
| Example 2 | 0.03014 | 3.37 × 10⁵ | 2.87 × 10⁻⁷ | 8.51 × 10⁻¹³ |

As may be seen from the results of Table 1, the organic thin film transistors fabricated in Examples 1 and 2, each of which may include the organic thin film of example embodiments, showed improved electrical properties, e.g., increased charge carrier mobility and increased on-current (Iₒₙ), compared to the organic thin film transistors fabricated in Comparative Examples 1 and 2.

As apparent from the above description, the method of example embodiments may enable the formation of a dense, uniform, highly ordered organic thin film with improved physical properties and improved surface characteristics by a wet process in an economical and simple manner. Therefore, the use of the organic thin film as a gate insulating layer or a semiconductor layer may facilitate the fabrication of an organic electronic device having improved electrical properties, e.g., increased charge carrier mobility.

Although example embodiments have been disclosed for illustrative purposes, those skilled in the art will appreciate that various modifications, additions and substitutions are possible, without departing from the scope and spirit of the accompanying claims.

What is claimed is:

1. A method for forming an organic thin film, comprising:
applying a non-solvent and a composition including an organic material and a good solvent to a substrate to form a thin film.

2. The method according to claim 1, wherein the non-solvent is added to the composition including an organic material and a good solvent, and the mixture is applied to the substrate to form the thin film.

3. The method according to claim 1, wherein the composition including an organic material and a good solvent is applied to the substrate, and the non-solvent is applied thereto to form the thin film.

4. The method according to claim 1, wherein the non-solvent is applied to the substrate, and the composition including an organic material and a good solvent is applied thereto to form the thin film.

5. The method according to claim 1, wherein the organic material is an organic semiconductor material or an organic insulating material.

6. The method according to claim 5, wherein the organic semiconductor material is at least one material selected from the group consisting of anthracene, tetracene, pentacene, melocyanine, copper phthalocyanine, perylene, rubrene, coronen, anthradithiophene, polyfluorene, polyacetylene, polydiacetylene. polypyrrole, polythiophene, oligothiophene, polyselenophene, polyisothianaphthene, polyarylenevinylene, polyaniline, polyazulene, polypyrene, polycarbazole, polyfuran, polyphenylene, polyindole, polypyridazine, polyacene, polythienylthiazole, and derivatives thereof, and
the organic insulating material is at least one material selected form the group consisting of polyimide, benzocyclobutene, parylene, polyacrylate, polyvinyl alcohol, polyvinylphenol, and derivatives thereof.

7. The method according to claim 1, wherein the good solvent is a solvent having a solubility of about 0.05% to about 20% by weight for the organic material and the non-solvent is a solvent having a solubility of about 0.001% to less than about 0.05% by weight for the organic material.

8. The method according to claim 1, wherein the good solvent is a solvent having a solubility of about 1% to about 10% by weight for the organic material and the non-solvent is a solvent having a solubility of about 0.01% to about 0.03% by weight for the organic material.

9. The method according to claim 1, wherein the composition includes about 0.1% to about 50% by weight of the organic material and about 50% to about 99.9% by weight of the good solvent.

10. The method according to claim 1, wherein the substrate is a transparent substrate, or is made of a semiconductor material or an insulating material.

11. The method according to claim 1, wherein the application is carried out by printing, ink-jetting, drop casting, dip coating, spin casting, stamping, screen printing, or solution-casting.

12. The method according to claim 1, wherein the surface of the substrate is pretreated.

13. The method according to claim 12, wherein the surface-treatment is carried out by a method using a self-assembled monolayer, a method using a buffer layer, or a method for varying surface physical properties.

14. The method according to claim 1, wherein the method further includes annealing the thin film at about 50° C. to about 200° C. for about one minute to about one hour.

15. The method according to claim 2, wherein the volume ratio of the good solvent to the non-solvent added is from about 1:1 to about 1,000:1.

16. An organic thin film formed by the method according to claim 1.

17. An organic electronic device comprising the organic thin film according to claim 16 as a gate insulating layer and a semiconductor layer.

18. The organic electronic device according to claim 17, wherein the organic electronic device is a thin film transistor, a solar cell, or a polymer memory device.
